(19) United States
(12) Patent Application Publication
(10) Pub. No.: US 2012/0250248 A1
(43) Pub. Date: Oct. 4, 2012

(54) PORTABLE ELECTRONIC DEVICE WITH CONDUCTIVE FOAM

(75) Inventors: HONG LI, Shenzhen City (CN); XUE-DONG TANG, Shenzhen City (CN); XIAO-HUI ZHOU, Shenzhen City (CN); HAI-TAO WANG, Shenzhen City (CN)

(73) Assignees: HON HAI PRECISION INDUSTRY CO., LTD., Tu-Cheng (TW); HONG FU JIN PRECISION INDUSTRY (ShenZhen) Co., Ltd., Shenzhen City (CN)

(21) Appl. No.: 13/211,325

(22) Filed: Aug. 17, 2011

(30) Foreign Application Priority Data
Mar. 28, 2011 (CN) 201110074945.4

(51) Int. Cl. H05K 7/20

(52) U.S. Cl. 361/679.54

(57) ABSTRACT

A portable electronic device comprises a motherboard with an electronic component mounted thereon, an electrical conducting port disposed on the motherboard, a heat dissipation plate for dissipating heat of the electronic component, and conductive foam placed between the electrical conducting port and the heat dissipation plate. The heat dissipation plate has a protrusion extending therefrom corresponds to the electrical conducting port. The conductive foam defines a hole, and the protrusion of the heat dissipation plate extends through the hole of the conductive foam to contact the electrical conducting port.

### BACKGROUND

1. Technical Field

The disclosure relates to portable electronic devices and, more particularly, to a portable electronic device having conductive foam.

2. Description of Related Art

The conventional electronic devices, such as notebook computers, always have many electrical conducting ports. In use, static electricity may accumulate on the electrical conducting ports of the electronic device, so the electrical conducting ports must be grounded to transfer the static electricity.

In practice, the static electricity accumulated on the electrical conducting ports can be transferred to a heat sink located in the electronic device via a conductive foam, and the static electricity on the heat sink can be transferred to the ground via the motherboard in the electronic device. However, the conductive foam in the electronic device is not always fixed, so it is not easy to attach the conductive foam in the right location for an operator, thus, the conductive foam may fall off from the electronic device easily.

Therefore, there is room for improvement in the art.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is an isometric view of a portable electronic device having conductive foam in accordance with an embodiment of the disclosure.

FIG. 2 is an isometric enlarged partial view of the conductive foam in FIG. 1.

FIG. 3 is an isometric, exploded view of the portable electronic device of FIG. 1.

FIG. 4 is an isometric enlarged reverse view of a heat dissipation plate and the conductive foam of the portable electronic device in FIG. 3.

FIG. 5 is an isometric enlarged partial view of the heat dissipation plate and the conductive foam in FIG. 4.

### DETAILED DESCRIPTION

While this disclosure are embodiments in many different forms, they are shown in the Figures and will herein be described in detail, preferred embodiments of the disclosure with the understanding that the present disclosure is to be considered as an exemplification of the principles of the disclosure, and is not intended to limit the broad aspects of the disclosure to the embodiments illustrated.

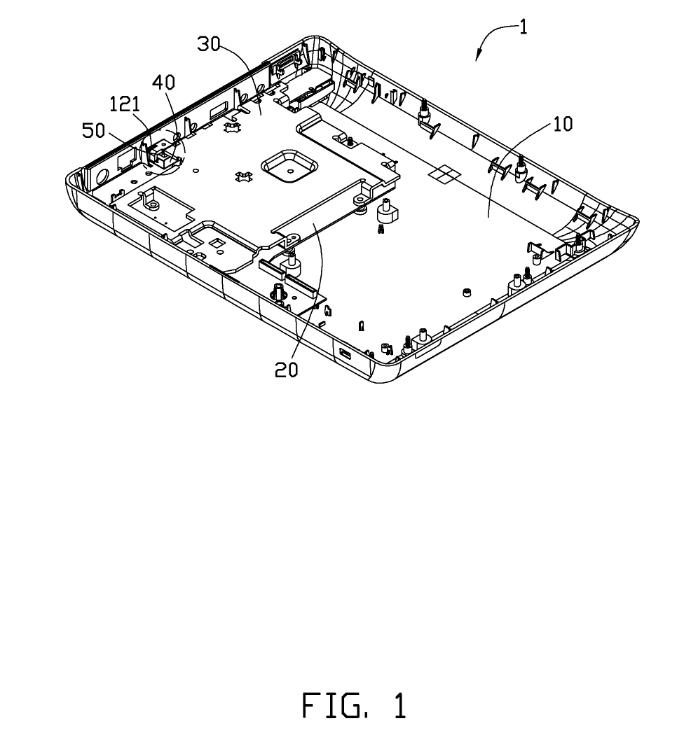

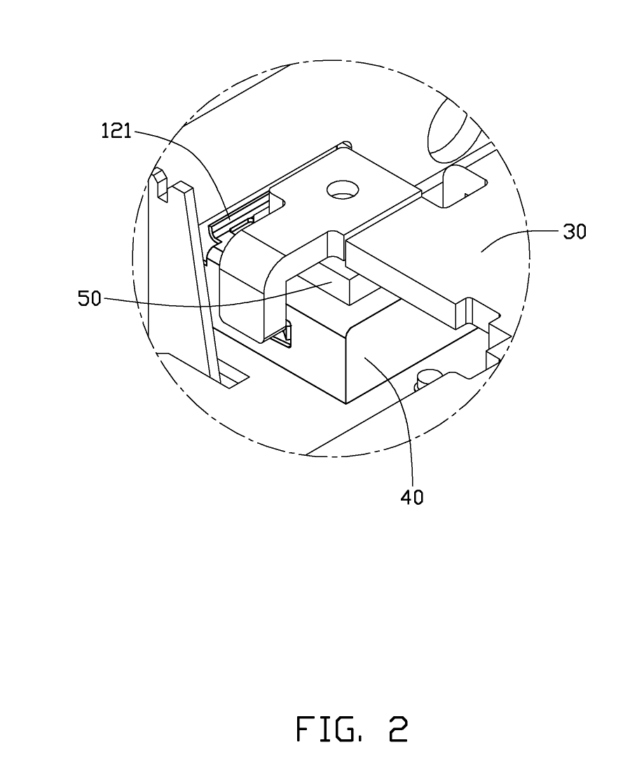

Referring to FIGS. 1 and 2, a portable electronic device 1 in accordance with an embodiment of the disclosure is shown. The portable electronic device 1 can be a notebook computer. The portable electronic device 1 includes a concave base 10; a motherboard 20 received in the base 10. A heat dissipation plate 30 electrically connected to the motherboard 20; an electrical conducting port 40 located at one side of the motherboard 20 connecting an outer element; and a conductive foam 50 placed between the motherboard 20 and the heat dissipation plate 30.

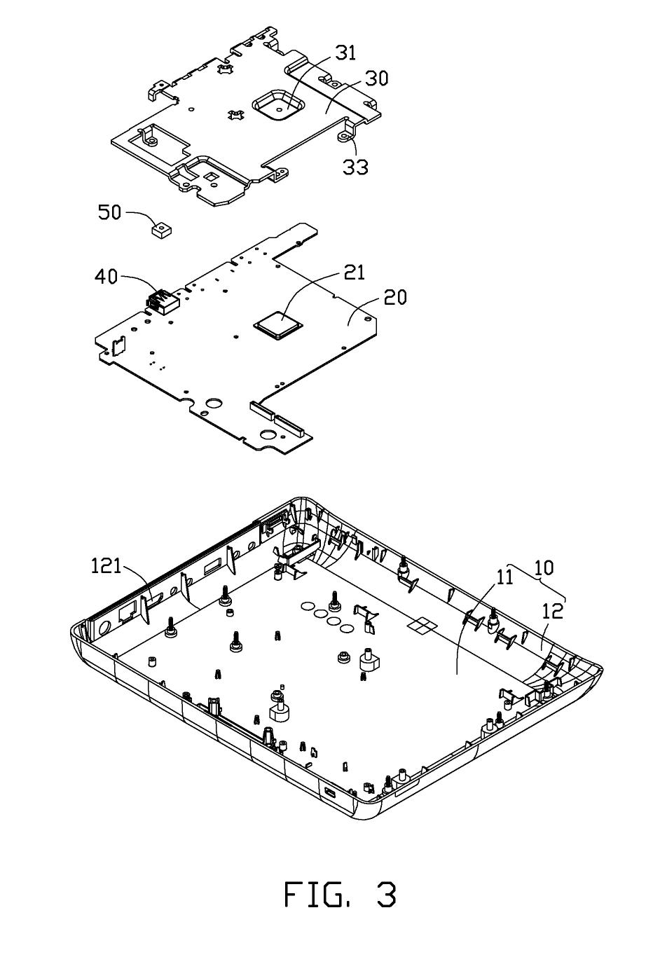

Referring to FIG. 3, the base 10 has a rectangular substrate 11 and four continuous side walls 12 perpendicular to the substrate 11. One side wall 12 defines an opening 121, and the electrical conducting port 40 can be received in the opening 121. The motherboard 20 is placed to engagingly attach to the side wall 12 which defines the opening 121. The motherboard 20 has an electronic component 21 mounted thereon. The electrical conducting port 40 is disposed at an edge of the base 10 facing the opening 121. The electrical conducting port 40 is aligned with the opening 121 of the side wall 12, and is electrically connected with the motherboard 20.

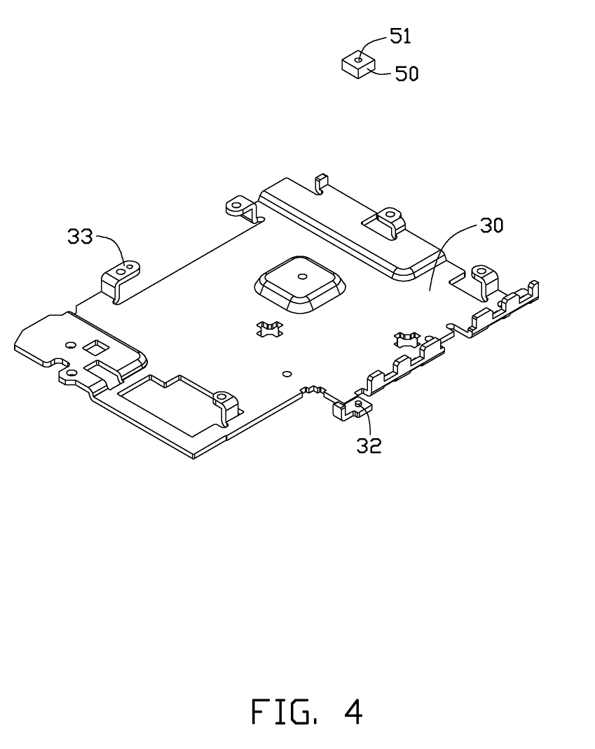

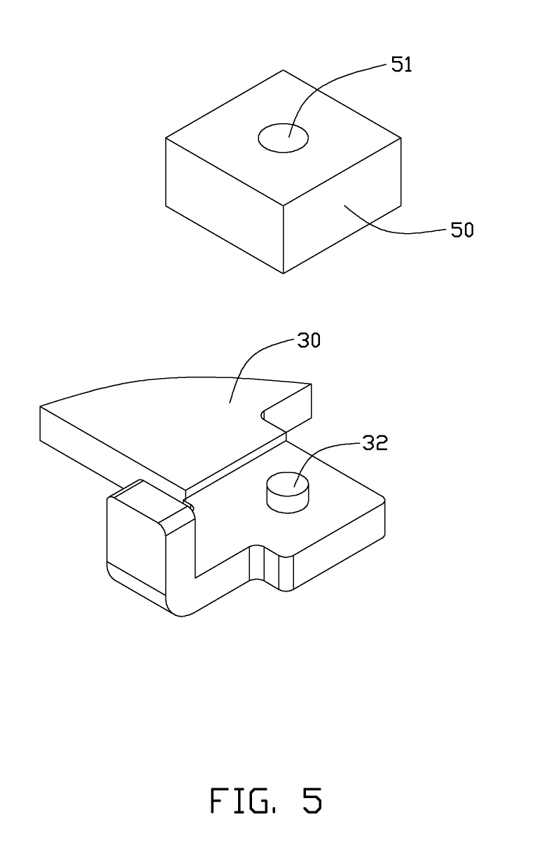

Referring to FIGS. 4 and 5, the heat dissipation plate 30 covers and is in contact with the motherboard 20 to dissipate heat generated by the electronic component 21. The heat dissipation plate 30 defines a recess 31 aligned with the electronic component 21 of the motherboard 20, the recess 31 is pressed firmly against the electronic component 21 when the heat dissipation plate 30 is assembled onto the motherboard 20. A bottom surface of the heat dissipation plate 30 defines a protrusion 32. The protrusion 32 corresponds to the electrical conducting port 40. In the present embodiment, the protrusion 32 is a cylindrical pole. In other embodiments, the protrusion 32 may be a prismoid or other shapes. The heat dissipation plate 30 has a number of fixed feet 33 connecting to the motherboard 20.

In some embodiments, an outside surface of the conductive foam 50 always has cohesive property. The conductive foam 50 has a hole 51 defined therein, and the hole 51 corresponds to the protrusion 32 of the heat dissipation plate 30. The conductive foam 50 is attached on the electrical conducting port 40, and the protrusion 32 of the heat dissipation plate 30 extends through the hole 51 of the conductive foam 50 to contact the electrical conducting port 40, such that the conductive foam 50 is fixed and thus difficult to fall off. Furthermore, when the heat dissipation plate 30 is assembled on the motherboard 20, the conductive foam 50 can be compressed to firmly contact the electrical conducting port 40. Therefore, the electrical conducting port 40 can be electrically connected with the heat dissipation plate 30 via the conductive foam 50. The conductive foam 50 can be in any shaped and any dimension according to the demand of practical application.

In use, static electricity may accumulate on the electrical conducting port 40, the static electricity can be transferred to the heat dissipation plate 30 via the conductive foam 50, and then transferred to the motherboard 20 via the fixed feet 33 of the heat dissipation plate 30. Actually, the motherboard 20 is connected directly to the ground, so the static electricity input onto the motherboard 20 can be finally dissipated to ground.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A portable electronic device, comprising:
a motherboard with an electronic component mounted thereon;
an electrical conducting port disposed on the motherboard;
a heat dissipation plate for dissipating heat of the electronic component, the heat dissipation plate having a protrusion extending therefrom corresponding to the electrical conducting port; and
a conductive foam placed between the electrical conducting port and the heat dissipation plate, the conductive foam having a hole defined therein, the protrusion of the heat dissipation plate extending through the hole of the conductive foam to contact the electrical conducting port.

2. The portable electronic device as claimed in claim 1, wherein the heat dissipation plate covers the motherboard and the electrical conducting port.

3. The portable electronic device as claimed in claim 1, wherein the heat dissipation plate defines a recess aligned with the electronic component of the motherboard, and the recess is pressed firmly against the electronic component.

4. The portable electronic device as claimed in claim 1, further comprising a base, the base has a rectangular substrate and four continuous side walls perpendicular to the substrate, one side wall defines an opening, and the electrical conducting port is received in the opening.

5. The portable electronic device as claimed in claim 1, wherein the protrusion is a cylindrical pole.
